(19) United States
(12) Patent Application Publication
(10) Pub. No.: US 2012/0326267 A1
(43) Pub. Date: Dec. 27, 2012

(54) COMPOSITE ISOLATION LAYER STRUCTURES FOR SEMICONDUCTOR DEVICES AND METHODS OF MANUFACTURING THE SAME

(75) Inventor: Hyun-Seung Song, Namdong-gu (KR)

(73) Assignee: Samsung Electronics Co., Ltd.

(21) Appl. No.: 13/533,361

(22) Filed: Jun. 26, 2012

(30) Foreign Application Priority Data
Jun. 27, 2011 (KR) 10-2011-0062104

(51) Int. Cl. H01L 23/58; H01L 21/762

(52) U.S. Cl. 257/506; 438/435; 257/E23.002; 257/E21.546

(57) ABSTRACT

An isolation structure includes an oxide region in a lower portion of a trench on a substrate, an oxide layer conforming to a sidewall of the trench in an upper portion of the trench above the oxide region and a nitride region in the upper portion of the trench on the oxide region and the oxide layer. The substrate may include silicon, the oxide region may include silicon oxide and the nitride region may include silicon nitride. The oxide region may have a thickness of more than half of a height from a bottom of the trench to a top of the trench.

### CROSS-REFERENCE TO RELATED APPLICATION

This application claims priority under 35 USC §119 to Korean Patent Application No. 10-2011-0062104 filed on Jun. 27, 2011 in the Korean Intellectual Property Office (KIPO), the contents of which are herein incorporated by reference in their entirety.

### BACKGROUND

Example embodiments relate to semiconductor devices and methods of fabricating the same and, more particularly, to isolation structures for semiconductor devices and methods of fabricating the same.

As the integration degree of semiconductor devices increases, isolation structures used therein have become smaller. In some devices, distances between isolation structures and buried gate structures adjacent thereto have become smaller, which may deteriorate characteristics of transistors including such buried gate structures.

### SUMMARY

In some embodiments, an isolation structure includes an oxide region in a lower portion of a trench on a substrate, an oxide layer conforming to a sidewall of the trench in an upper portion of the trench above the oxide region and a nitride region in the upper portion of the trench on the oxide region and the oxide layer. The substrate may include silicon, the oxide region may include silicon oxide and the nitride region may include silicon nitride. The oxide region may have a thickness of more than half of a height from a bottom of the trench to a top of the trench.

Further embodiments provide methods of forming isolation structures. A trench is formed a substrate. An oxide region is formed in a lower portion of the trench, leaving a portion of a sidewall of the trench above the oxide region exposed. An oxide layer is formed on the exposed sidewall of the trench. A nitride region is formed in an upper portion of the trench on the oxide region and the oxide layer. Forming an oxide layer on the exposed portion of the sidewall of the trench may include thermally oxidizing the exposed portion of the sidewall of the trench.

In further embodiments, a semiconductor device includes a substrate and an isolation structure including an oxide region disposed in a lower portion of a trench in the substrate, an oxide layer conforming to a sidewall of the first trench above the oxide region and a nitride region disposed on the oxide region in the trench. The device further includes a buried gate structure in the substrate adjacent the isolation layer structure and an impurity region disposed between the buried gate structure and the isolation layer structure.

The buried gate structure may include a gate insulation layer, a gate electrode and a capping layer pattern in a second trench on the substrate. The gate electrode may include a metal. The gate insulation layer may conform to a sidewall of the second trench and the gate electrode and the capping layer pattern may be disposed in the second trench. The buried gate structure and the impurity region may be components of a transistor.

In further embodiments, the substrate has a cell region and a peripheral circuit region. The memory cells may be disposed in the cell region and peripheral circuits may be disposed in the peripheral region. The buried gate structure may be disposed in the cell region and the semiconductor device may further include a gate structure in the peripheral region. The impurity region may include a plurality of impurity regions and the semiconductor device may further include a bit line electrically connected to a first one of the impurity regions and a capacitor electrically connected to a second one of the impurity regions.

### BRIEF DESCRIPTION OF THE DRAWINGS

Example embodiments will be more clearly understood from the following detailed description taken in conjunction with the accompanying drawings. FIGS. 1 to 8 represent non-limiting, example embodiments as described herein.

FIG. 1 is a cross-sectional view illustrating an isolation layer structure in accordance with example embodiments;

FIGS. 2 to 5 are cross-sectional views illustrating a method of forming an isolation layer structure in accordance with example embodiments;

FIG. 6 is a cross-sectional view illustrating a semiconductor device having an isolation layer structure in accordance with example embodiments;

FIGS. 7 to 15 are cross-sectional views illustrating a method of manufacturing a semiconductor device having an isolation layer structure in accordance with example embodiments;

FIG. 16 is a block-diagram illustrating a memory system including an isolation layer structure in accordance with example embodiments;

FIG. 17 is a block-diagram illustrating a display system including an isolation layer structure in accordance with example embodiments; and

FIG. 18 is a block-diagram illustrating a computer system including an isolation layer structure in accordance with example embodiments.

### DETAILED DESCRIPTION OF THE EMBODIMENTS

Various example embodiments will be described more fully hereinafter with reference to the accompanying drawings, in which some example embodiments are shown. The present inventive subject matter may, however, be embodied in many different forms and should not be construed as limited to the example embodiments set forth herein. Rather, these example embodiments are provided so that this description will be thorough and complete, and will fully convey the scope of the present inventive subject matter to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive subject matter.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive subject matter. As used herein, the singular forms “a,” “an” and “the” are intended to include a plurality of forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive subject matter.

Unless otherwise defined, all terms (including technical and scientific terms) used herein have the same meaning as commonly understood by one of ordinary skill in the art to which this inventive subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

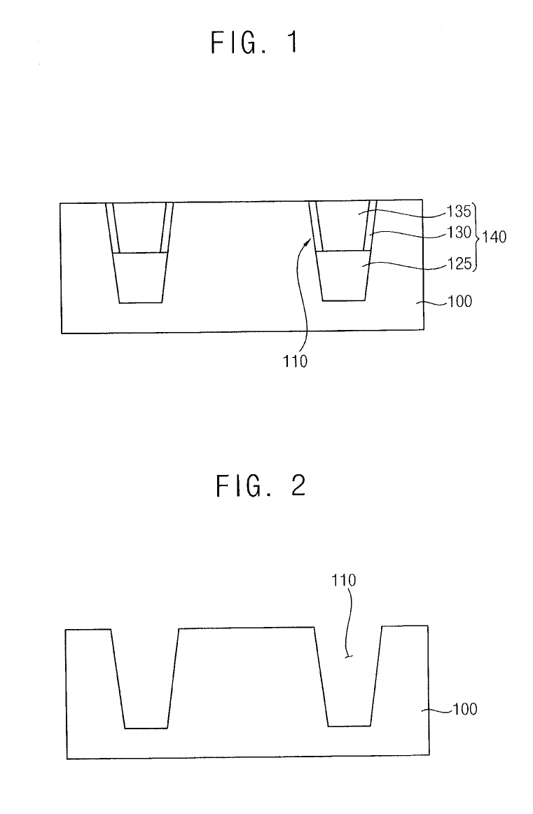

FIG. 1 is a cross-sectional view illustrating an isolation layer structure in accordance with example embodiments.

Referring to FIG. 1, an isolation layer structure 140 may include first and second isolation regions 125 and 135 and a sidewall oxide layer 130 filling a trench 110 on a substrate 100.

The substrate 100 may include a semiconductor substrate, e.g., a silicon substrate, a germanium substrate, a silicon-germanium substrate, etc., a silicon-on-insulator (SOI) substrate, a germanium-on-insulator (GOI) substrate, etc.

The first isolation region 125 may fill a lower portion of the trench 110. In example embodiments, the first isolation region 125 may include an oxide. In some embodiments, the first isolation region 125 may have a thickness of more than half of a depth of the trench 110.

The sidewall oxide layer 130 may be formed on a sidewall of a portion of the trench 110 which is not filled by the first isolation region 125. In example embodiments, the sidewall oxide layer 130 may include silicon oxide. In some example embodiments, the sidewall oxide layer 130 may have a thickness of about 50 Å to about 200 Å.

The second isolation region 135 may be formed on the first isolation region 125 and the sidewall oxide layer 130 to fill a remaining portion of the trench 110. In example embodiments, the second isolation region 135 may include a nitride.

The isolation layer structure 140 may include the first isolation region 125 having oxide at a lower portion thereof and the second isolation region 135 having nitride at an upper portion thereof, thereby having better characteristics than an isolation layer having only one of an oxide or a nitride at both of lower and upper portions thereof. That is, if the isolation layer includes only an oxide, a buried metal gate electrode adjacent to the isolation layer may be oxidized. In contrast, in some embodiments of the inventive subject matter, the isolation layer structure 140 includes nitride adjacent to a buried metal gate electrode, so that the metal gate electrode may not be oxidized.

Further, if the isolation layer includes nitride only, a threshold voltage of a transistor adjacent to the isolation layer may decreased due to positive charges in the isolation layer, and thus the isolation characteristics of the isolation layer may be deteriorated. In contrast, according to example embodiments, the isolation layer structure 140 includes oxide also, and thus the isolation layer structure 140 may have fewer positive charges. Therefore, the threshold voltage characteristics of the transistor and the isolation characteristics of the isolation layer structure 140 may deteriorate less.

FIGS. 2 to 5 are cross-sectional views illustrating operations for forming an isolation layer structure in accordance with example embodiments.

Referring to FIG. 2, a trench 110 may be formed on the substrate 100. The substrate 100 may include a semiconductor substrate, e.g., a silicon substrate, a germanium substrate, a silicon-germanium substrate, etc., a SOI substrate, a GOI substrate, etc.

In example embodiments, a pad oxide layer and a hard mask layer may be sequentially formed on the substrate 100, and the hard mask layer may be patterned to form a hard mask by a photolithography process. The pad oxide layer and an upper portion of the substrate may be etched using the hard mask as an etching mask to form the trench 110.

The pad oxide layer may be formed by a thermal oxidation process on an upper portion of the substrate 100. The hard mask layer may be formed using a material having an etching selectivity with respect to the pad oxide layer, e.g., silicon nitride.

The pad oxide layer and the hard mask may be removed. In some embodiments, the pad oxide layer and the hard mask may be removed when a planarization process is performed for forming a second isolation region 135 subsequently formed that may be illustrated in FIG. 1 later.

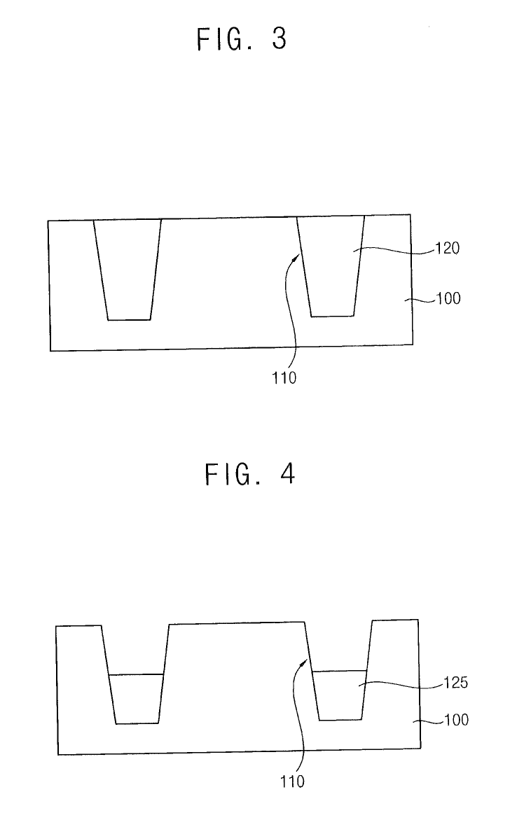

Referring to FIG. 3, a first isolation layer 120 may be formed to fill the trench 110.

In example embodiments, an oxide layer may be formed on the substrate 100 to fill the trench 110, and an upper portion of the oxide layer may be planarized until a top surface of the substrate 100 is exposed to form the first isolation layer 120.

The oxide layer may be formed by a chemical vapor deposition (CVD) process, a high density plasma chemical vapor deposition (HDP-CVD) process, etc. The planarization may be performed by a chemical mechanical polishing (CMP) process and/or an etch-back process.

Referring to FIG. 4, an upper portion of the first isolation layer 120 may be removed to form a first isolation region 125 at a lower portion of the trench 110. In example embodiments, the removal may be performed by a dry etching process. In some example embodiments, the first isolation region 125 may be formed to have a thickness of more than half of a distance from a bottom surface of the trench 110 to a top surface of the substrate 100.

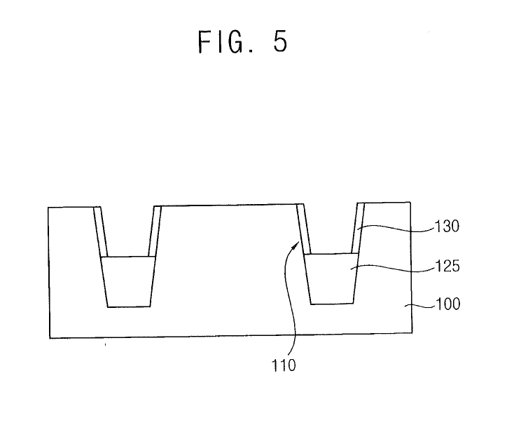

Referring to FIG. 5, a sidewall oxide layer 130 may be formed on a sidewall of a portion of the trench 110 not filled by the first isolation region 125. In example embodiments, the sidewall oxide layer 130 may be formed by a thermal oxidation process on a portion of the substrate 100 exposed by the trench 110. When the substrate 100 includes silicon, the sidewall oxide layer 130 may include silicon oxide. Alternatively, the sidewall oxide layer 130 may be formed by a CVD process using an oxide such as silicon oxide.

In some embodiments, the sidewall oxide layer 130 may have a thickness of about 50 Å to about 200 Å. Accordingly, even if the trench 110 has a narrow width, the second isolation region 135 (refer to FIG. 1) may be formed without voids therein to fill the remaining portion of the trench 110.

The sidewall oxide layer 130 may cure a damage of the substrate 100 generated in the formation of the trench 110, and buffer a stress to the substrate 100 applied by the second isolation region 135 (refer to FIG. 1).

Referring to FIG. 1 again, the second isolation region 135 may be formed on the first isolation region 125 to fill the remaining portion of the trench 110. In example embodiments, the second isolation layer may be a nitride region formed on the first isolation region 125, the sidewall oxide layer 140 and the substrate 100 by a CVD process. An upper portion of the second isolation layer may be planarized until a top surface of the substrate 100 is exposed to form the second isolation region 135.

Accordingly, the isolation layer structure 140 may be formed. The isolation layer structure 140 may include the first and second isolation regions 125 and 135 and the sidewall oxide layer 130 filling the trench 110.

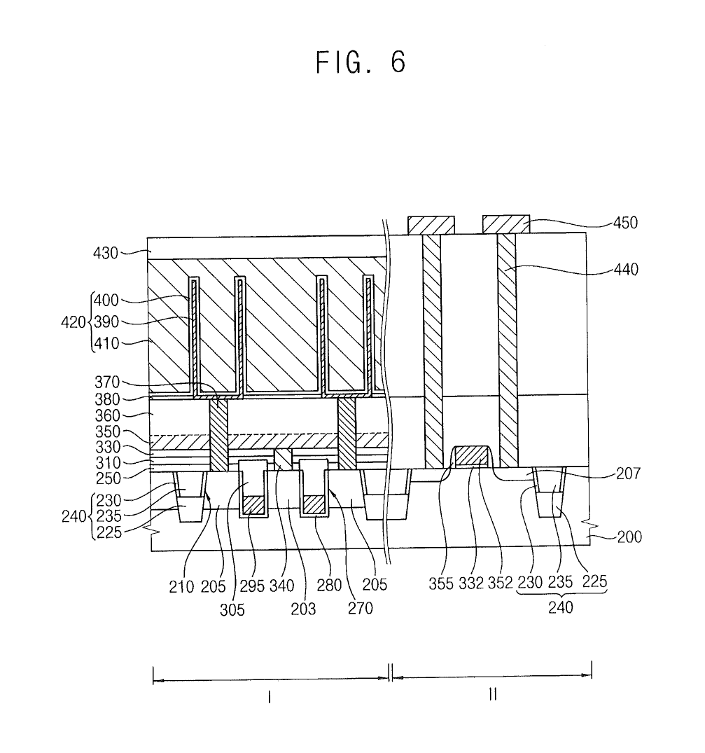

FIG. 6 is a cross-sectional view illustrating a semiconductor device having an isolation layer structure in accordance with example embodiments. The isolation layer structure shown in FIG. 6 may be substantially the same as the isolation layer structure 140 illustrated with reference to FIG. 1.

Referring to FIG. 6, the semiconductor device may include an isolation layer structure 240, first and second gate structures, impurity regions 203, 205 and 207, a bit line 350 and a capacitor 420. Additionally, the semiconductor device may further include wirings 450 electrically connected to the impurity regions 203, 205 and 207.

The isolation layer structure 240 may include first and second isolation regions 225 and 235 and a sidewall oxide layer 230. The first and second isolation regions 225 and 235 and the sidewall oxide layer 230 may fill a first trench 210 formed in a substrate 200. The first and the second isolation regions 225 and 235 may have oxide and nitride, respectively, and the sidewall oxide layer 230 may have oxide. The isolation layer structure 240 may have better isolation characteristics than that of an isolation layer having a nitride only.

Further, the substrate 200 may include a first region I in which memory cells may be formed and a second region II in which peripheral circuits may be formed.

The first gate structure may include a first gate insulation layer 280, a first gate electrode 295 and a capping layer pattern 305 sequentially stacked. The first gate insulation layer 280, the first gate electrode 295 and the capping layer pattern 305 may fill a second trench 270 formed in the first region I of the substrate 200.

The first gate insulation layer 280 may be conformally formed on an inner wall of the second trench 270 and have silicon oxide or a metal oxide.

The first gate electrode 295 may fill a lower portion of the second trench 280 on the first gate insulation layer 280. In example embodiments, the first gate electrode 295 may have a metal, e.g., tungsten (W), titanium nitride (TiN), etc., a metal nitride and/or a metal silicide.

The capping layer pattern 305 may fill a remaining portion of the second trench 270, that is, an upper portion of the second trench 270, on the first gate electrode 295. In example embodiments, the capping layer pattern 305 may have silicon oxide.

The first gate structure may include the first gate electrode 295 having a metal as a buried gate structure in the substrate 200. The isolation layer structure 240 may have not only oxide but also nitride, so that the first gate electrode 295 may be hardly oxidized by the isolation layer structure 240.

The second gate structure may include a second gate insulation layer pattern 332 and a second gate electrode 352 sequentially stacked in the second region II of the substrate 200, and a spacer 355 may be further formed on a sidewall of the second gate structure.

The second gate insulation layer pattern 332 may have silicon oxide, the second gate electrode 352 may have a metal, a metal nitride, a metal silicide and/or a doped polysilicon, and the spacer may have silicon nitride.

The first gate structure and a first and second impurity regions 203 and 205 in the first region I may define a first transistor, and the second gate structure and a third impurity region 207 in the second region II may define a second transistor.

The isolation layer structure 240 may have an upper nitride portion and a lower oxide portion so that a threshold voltage of the transistors, especially of the first transistor, may be less affected by positive charges from the nitride of the isolation layer structure 240.

The bit line 350 may be electrically connected to the first impurity region 203, and have a metal, a metal nitride, a metal silicide and/or doped polysilicon. Particularly, the bit line 350 may be electrically connected to the first impurity region 203 by a first plug 340. The first plug 340 may be formed through a mask 250, a blocking layer 310 and a silicon oxide layer 330 sequentially stacked in the first region I of the substrate to make contact with a top surface of the first impurity region 203.

The mask 250 may include silicon oxide, and the blocking layer 310 may include silicon nitride.

The capacitor 420 may be electrically connected to the second impurity region 205, and include a lower electrode 390, a dielectric layer 400 and an upper electrode 410 sequentially stacked. The lower electrode 390 and the upper electrode 410 may have a metal, a metal nitride, a metal silicide and/or doped polysilicon. The dielectric layer 400 may have a high-k dielectric material having a dielectric constant substantially the same as or higher than that of silicon nitride, e.g., tantalum oxide, hafnium oxide, aluminum oxide, zirconium oxide, etc.

A first insulating interlayer 360 may be formed on the substrate 200 to cover the bit line 350, the second gate structures and the spacer 355. The capacitor 420 may be formed on the first insulating interlayer 360 and make contact with second plugs 370 that is formed through the first insulating interlayer 360, the silicon oxide layer 330, the blocking layer 310 and the mask 250. Further, an etch stop layer 380 may be formed between the dielectric layer 400 of the capacitor 420 and the first insulating interlayer 360.

A wiring 450 may be formed on the second insulating interlayer 430 to cover the capacitor 420, and be electrically connect to the third impurity region 207 by a third plug 440. The third plug 440 may be formed on the third impurity region 207 through the first and second insulating interlayers 360 and 430. The wiring 450 may include a metal, a metal nitride, a metal silicide and/or doped polysilicon.

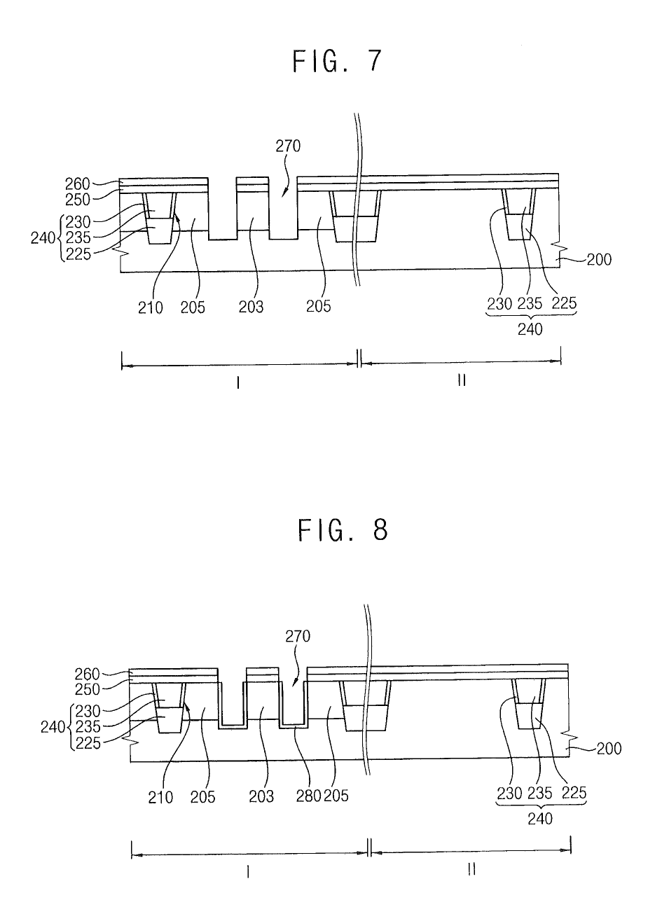

FIGS. 7 to 15 are cross-sectional views illustrating operations for fabricating a semiconductor device having an isolation layer structure in accordance with example embodiments. These operations include operations substantial similar to the operations described above with reference to FIGS. 2 to 5.

Referring to FIG. 7, impurity regions 203 and 205 may be formed by implanting impurities into an upper portion of a first region I of a substrate 200. Further, an isolation layer structure 240 may be formed on the substrate 200 to divide the substrate 200 into an active region and a field region. The isolation layer structure 240 may be formed by forming a first trench 210 on the substrate 200 and filling the trench 210 using first and second isolation regions 225 and 235 and a sidewall oxide layer 230.

The substrate 200 may include the first region I in which memory cells may be formed and a second region II in which peripheral circuits may be formed.

In example embodiments, the impurities may have n-type impurities, e.g., phosphorus (P), arsenic (As), etc. The impurity regions 203 and 205 may serve as source/drain regions of the memory cells.

Further, an upper portion of the substrate 200 may be removed to form a second trench 270.

In example embodiments, a mask layer and an etch stop layer may be formed on the substrate 200, and the mask layer and the etch stop layer may be patterned by a photolithography process to form a mask 250 and an etch stop layer pattern 260. An upper portion of the substrate 200 may be removed using the mask 150 and the etch stop layer pattern 260 as an etching mask to form a second trench 270 that may be defined by a recessed upper portion of the substrate 200 and sidewalls of the mask 250 and the etch stop layer pattern 260. That is, the second trench 270 may be defined as a space that may be formed by the recessed upper portion of the substrate 200 and the sidewalls of the mask 250 and the etch stop layer pattern 260.

The mask layer may be formed using silicon oxide, and the etch stop layer may be formed using silicon nitride. The impurity regions 203 and 205 may be divided into a first impurity region 203 and a second impurity region 205 by the second trench 270.

Referring to FIG. 8, a first gate insulation layer 280 may be formed on the recessed upper portion of the substrate 200 exposed by the second trench 270.

In example embodiments, a thermal oxidation process may be performed on the recessed upper portion of the substrate 200 to form the first gate insulation layer 280. In other example embodiments, the first gate insulation layer 280 may be formed by depositing silicon oxide or a metal oxide by a CVD process. The metal oxide may have hafnium oxide (HfO₂), tantalum oxide (Ta₂O₅), zirconium oxide (ZrO₂), etc.

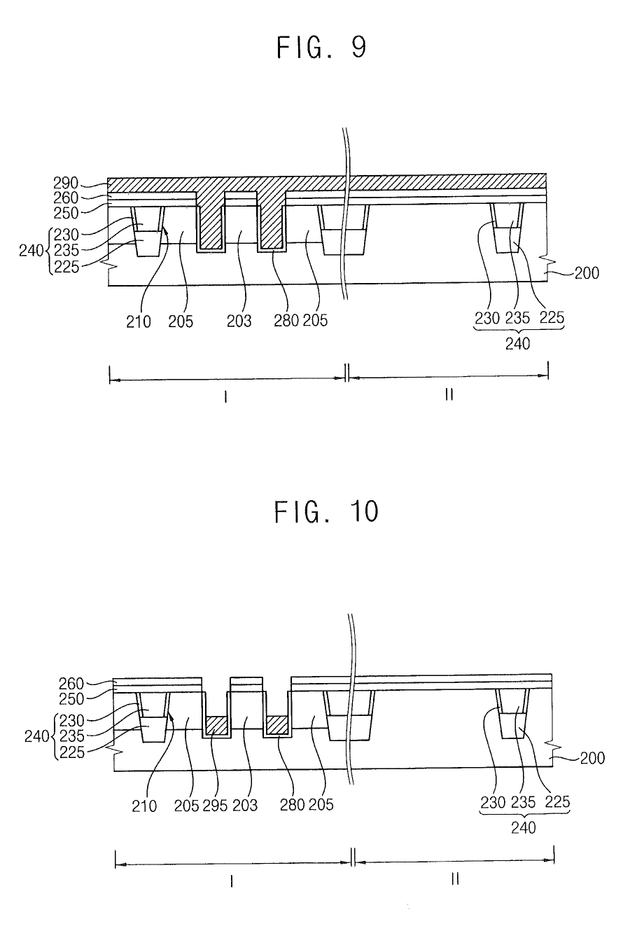

Referring to FIG. 9, a first gate electrode layer 290 may be formed on the first gate insulation layer 280, the mask 250 and the etch stop layer pattern 260 to fill the second trench 270. The first gate electrode layer 290 may be formed using a metal, e.g., tungsten (W), titanium nitride (TiN), etc., a metal nitride and/or a metal silicide by an atomic layer deposition (ALD) process, a physical vapor deposition (PVD) process, etc. A thermal annealing process, e.g., a rapid thermal annealing (RTA) process, a spike RTA process, a flash RTA process, a laser annealing process, etc., may be further performed on the first gate electrode layer 290.

Referring to FIG. 10, an upper portion of the first gate electrode layer 290 may be removed to form a first gate electrode 295 filling a portion of the second trench 270. In example embodiments, a top surface of the first gate electrode layer 290 may be planarized by a chemical mechanical polishing (CMP) process until a top surface of the etch stop layer pattern 260 is exposed. Additionally, a portion of the first gate electrode layer 290 in an upper portion of the second trench 270 may be further removed to form the first gate electrode 295. In example embodiments, the first gate electrode 295 may have a top surface substantially lower than that of the substrate 200.

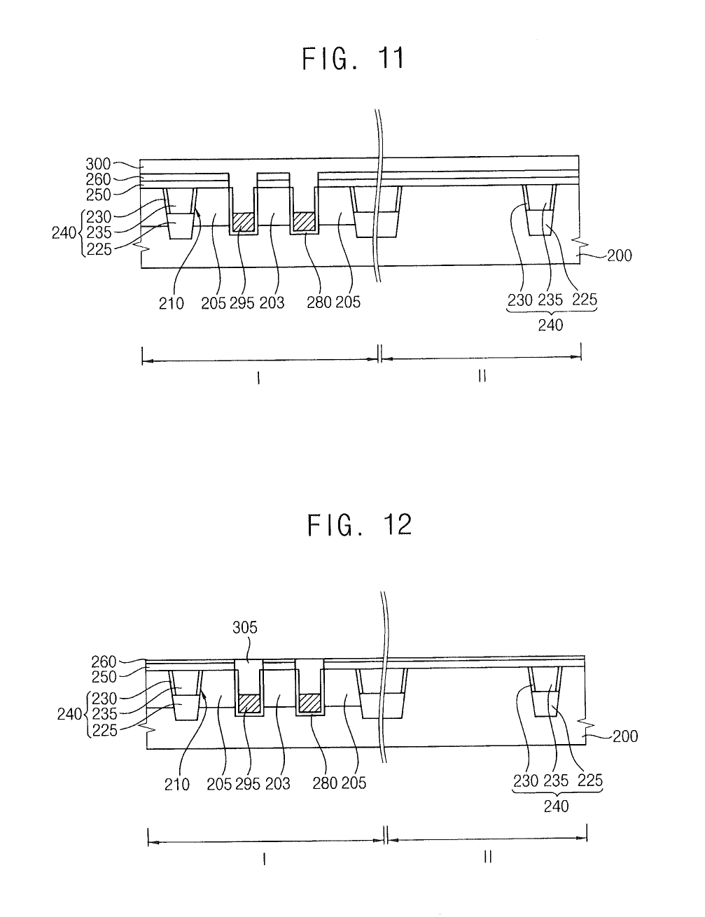

Referring to FIG. 11, a capping layer 300 may be formed on the first gate electrode 195, the first gate insulation layer 280, the mask 250 and the etch stop layer pattern 260 to fill a remaining portion of the second trench 270. In example embodiments, the capping layer 300 may be formed using silicon oxide.

Referring to FIG. 12, an upper portion of the capping layer 300 may be removed by a CMP process to form a capping layer pattern 305 filling the remaining portion of the second trench 270. The etch stop layer pattern 260 may serve as a polishing end point, and the etch stop layer pattern 260 may be partially or entirely removed in the CMP process. The first gate electrode 295, the first gate insulation layer 280 and the capping layer pattern 305 may form a first gate structure, i.e., a buried gate structure. Additionally, the first gate structure and the first and the second impurity regions 203 and 205 may form a first transistor.

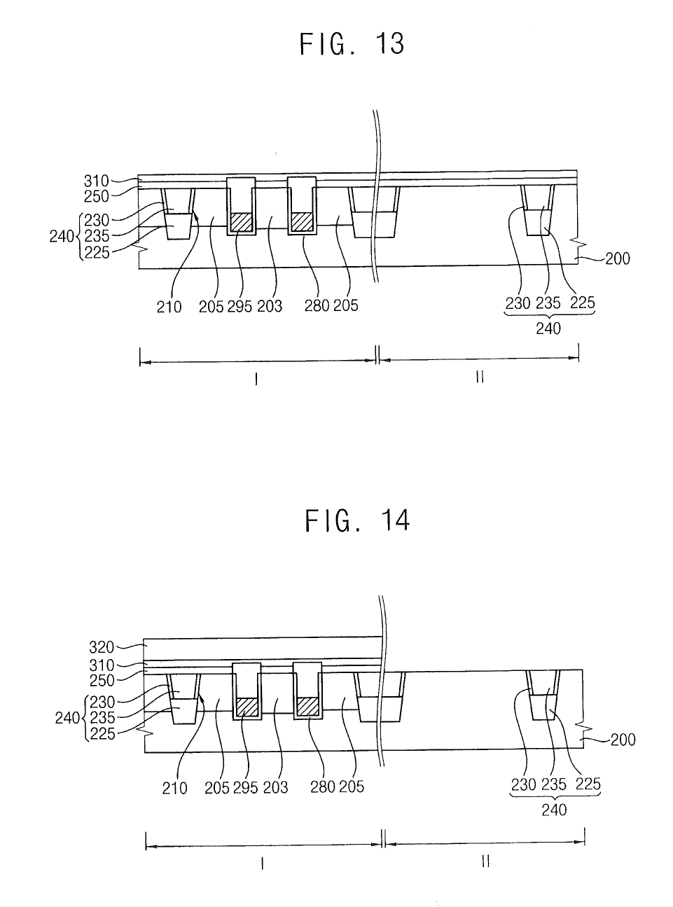

Referring to FIG. 13, a blocking layer 310 may be formed on the capping layer pattern 305 and a remaining portion of the etch stop layer pattern 260. In example embodiments, the blocking layer 310 may include silicon nitride. Accordingly, when a portion of the etch stop layer pattern 260 having silicon nitride remains, the remaining portion of the etch stop layer pattern 260 may be merged into the blocking layer 310.

Referring to FIG. 14, a photoresist pattern 320 may be formed on the blocking layer 310 to cover the first region I of the substrate 200. The blocking layer 310 and the mask 250 may be etched using the photoresist pattern 320 as an etching mask. Thus, the blocking layer 310 and the mask 250 may remain only in the first region I of the substrate 200 in which the memory cells may be formed.

In example embodiments, the etching process may be performed by a dry etching process using the photoresist pattern 320 as an etching mask. Thus, the photoresist pattern 320 may not lift during the etching process. The photoresist pattern 320 may be removed.

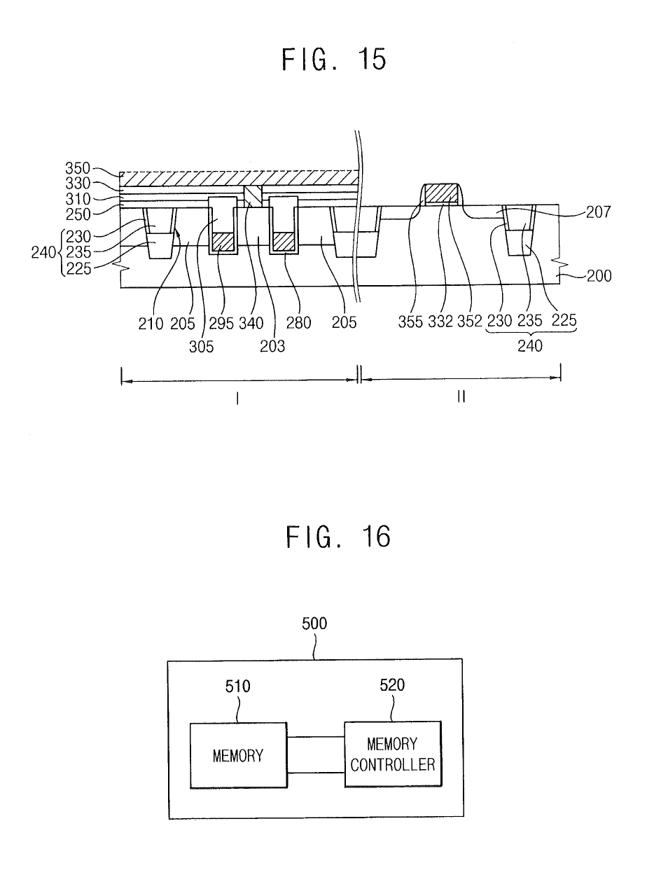

Referring to FIG. 15, a second gate insulation layer may be formed on the top surface of the substrate 200 in the second region II. In example embodiments, the second gate insulation layer may be formed by a CVD process using silicon oxide. When the second gate insulation layer is formed in the second region II, a silicon oxide layer 330 may be formed on the blocking layer 310 in the first region I.

After forming a first opening through the silicon oxide layer 330, the blocking layer 310 and the mask 250, a first conductive layer may be formed on the second gate insulation layer and the silicon oxide layer 330 to fill the first opening. An upper portion of the first conductive layer may be planarized until a top surface of the silicon oxide layer 330 is exposed to form a first plug 340. In example embodiments, the first conductive layer may include a metal, a metal nitride, a metal silicide and/or doped polysilicon.

A second conductive layer may be formed on the silicon oxide layer 330, the first plug 340 and the first conductive layer. In example embodiments, the second conductive layer may include a material substantially the same as the first conductive layer, and thus the first conductive layer may be merged into the second conductive layer in the second region II. The second conductive layer may be patterned to form a bit line 350 in the first region I and a second gate electrode 352 in the second region II. The bit line 350 may be electrically connected to the first plug 340.

In example embodiments, the second conductive layer may be patterned by a plasma etching process. In the plasma etching process, a top surface of the substrate 200 may be protected by the blocking layer 310 in the first region I. Thus, the first region I of the substrate 200 in which the memory cells may be formed may be protected from an etching damage of the plasma etching process.

As the second gate electrode 352 is formed on the substrate 200 in the second region II, the second gate insulation layer may be patterned using the second gate electrode 352 as an etching mask to form a second gate insulation layer pattern 332. The second gate electrode 352 and the second gate insulation layer pattern 332 may form a second gate structure.

A spacer 355 may be formed on a sidewall of the second gate structure, and a third impurity region 207 may be formed on a portion of the substrate 200 adjacent to the second gate structure.

Particularly, after forming a silicon nitride layer on the substrate 200 in the second region II to cover the second gate electrode 352 and the second gate insulation layer 332, the silicon nitride layer may be patterned by an anisotropic etching process to form the spacer 355. Additionally, the third impurity region 207 may be formed by an ion implantation process using the second gate structure and the spacer 355 as an ion implantation mask. The second gate structure and the third impurity region 207 may form a second transistor.

Referring to FIG. 6 again, a first insulating interlayer 360 may be formed on the silicon oxide layer 330 and the substrate 200 to cover the bit line 350, the second gate structure and the spacer 355. Second openings may be formed through the first insulating interlayer 360, the silicon oxide layer 330, the blocking layer 310 and the mask 250 to expose the second impurity regions 205. A third conductive layer may be formed on the second impurity regions 205 and the first insulating interlayer 360 to fill the second openings 360. The third conductive layer may be formed using a metal, a metal nitride, a metal silicide and/or doped polysilicon. A top surface of the third conductive layer may be planarized until a top surface of the first insulating interlayer 360 is exposed to form second plugs 370. The second plugs 370 may be electrically connected to the second impurity regions 205.

An etch stop layer 380 and a mold layer may be sequentially formed on the second plugs 370 and the first insulating interlayer 360. In example embodiments, the etch stop layer 380 may include silicon nitride, and the mold layer may include silicon oxide. Third openings (not illustrated) may be formed through the mod layer and the etch stop layer 380 to expose the second plugs 370. A fourth conductive layer may be formed on the exposed second plugs 370, the mold layer and sidewalls of the third openings. A sacrificial layer may be formed on the fourth conductive layer to fill remaining portions of the third openings. The fourth conductive layer may include a metal, a metal nitride, a metal silicide and/or doped polysilicon. Top surfaces of the sacrificial layer and the fourth conductive layer may be planarized until a top surface of the mold layer is exposed, and the sacrificial layer may be removed. Thus, a lower electrode 390 may be formed on the sidewalls of the third openings.

A dielectric layer 400 may be formed on the lower electrode 390 and the etch stop layer 380. The dielectric layer 400 may include silicon nitride or a high-k dielectric material having higher dielectric constant than that of silicon nitride, e.g., tantalum oxide, hafnium oxide, aluminum oxide, zirconium oxide, etc. An upper electrode 410 may be formed on the dielectric layer 400. The upper electrode 410 may include a metal, a metal nitride, a metal silicide and/or doped polysilicon. The lower electrode 390, the dielectric layer 400 and the upper electrode 410 may form a capacitor 420.

A second insulating interlayer 430 may be formed on the first insulating interlayer 360 to cover the capacitor 420. Fourth openings may be formed on the substrate 200 in the second region II through the second insulating interlayer 430 to expose the third impurity region 207. A fifth conductive layer may be formed on the exposed third impurity region 207 and the second insulating interlayer 430 to fill the fourth openings. An upper portion of the fifth conductive layer may be planarized until a top surface of the second insulating interlayer 430 is exposed to form a third plug 440. The third plug 440 may be electrically connected to the third impurity region 207, respectively.

Wiring 450 may be formed to be electrically connected to the third plug 440. A protection layer may be formed on the second insulating inter layer 430 to protect the wiring 450. Thus, a semiconductor device may be formed.

FIG. 16 is a block-diagram illustrating a memory system including an isolation layer structure in accordance with example embodiments.

Referring to FIG. 16, a memory system 50Q may include a memory 510 and a memory controller 520 connected to the memory 510.

The memory 510 may be a DRAM device including an isolation layer structure in accordance with example embodiments.

The memory controller 520 may provide an input signal for controlling the operation of the memory 510.

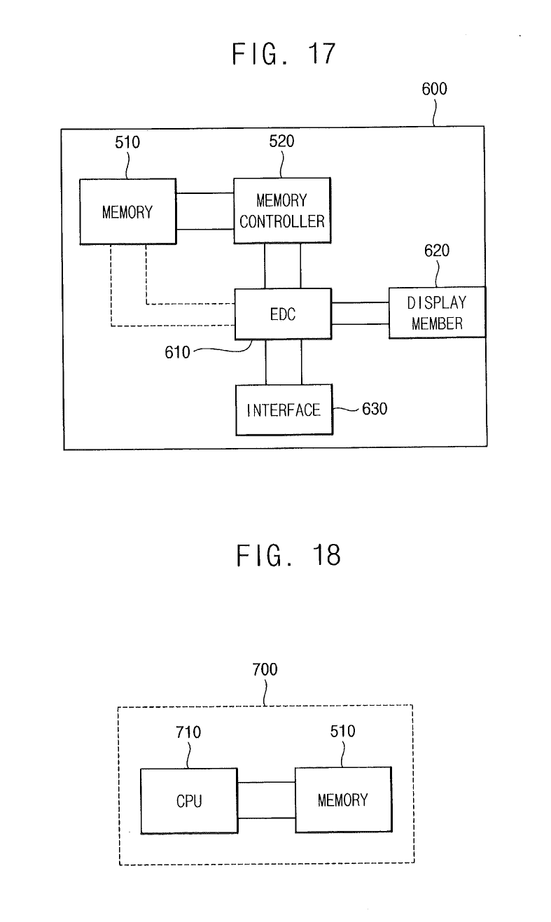

FIG. 17 is a block-diagram illustrating a display system including an isolation layer structure in accordance with example embodiments.

The display system may be a mobile device 600. The mobile device 600 may include a MP3 player, a video player, a complex of a video player and an audio player, etc. As illustrated in FIG. 17, the mobile device 600 may include a memory 510 and a memory controller 520. The mobile device 600 may also include an encoder/decoder (EDC) 610, a display member 610 and an interface 630.

The EDC 610 may input/output data into/from the memory 510 via the memory controller 520. As illustrated in a dotted line in FIG. 17, data may be input from the EDC 610 to the memory 510 directly, and data may be output from the memory 510 to the EDC 610 directly.

The EDC 610 may encode data for saving in the memory 510. For example, the EDC 610 may perform MP3 encoding to save audio data in the memory 510. Alternatively, the EDC 610 may perform MPEG encoding to save video data in the memory 510. Additionally, the EDC 610 may include a complex encoder for encoding different types of data according to different formats from each other. For example, the EDC 610 may include a MP3 encoder for audio data, and an MPEG encoder for video data.

The EDC 610 may decode an output from the memory 510. For example, the EDC 610 may perform MP3 decoding according to audio data output from the memory 510. Alternatively, the EDC 610 may perform MPEG decoding according to video data output from the memory 510. For example, the EDC 610 may include a MP3 decoder for audio data, and an MPEG decoder for video data.

The EDC 610 may include a decoder only. For example, encoder data may be input into the EDC 610, and be transferred to memory controller 520 and/or the memory 510.

The EDC 610 may receive data for encoding or encoded data via the interface 630. The interface 630 may follow standard (e.g., FireWire, USB, etc.). For example, the interface 630 may include a FireWire interface, an USB interface, etc. Data may be output from the memory 510 via the interface 630.

A display device 620 may display data input from the memory 510 or decoded by the EDC 610. For example, the display device 620 may include a speaker jack outputting audio data, a display screen outputting video data, etc.

FIG. 18 is a block-diagram illustrating a computer system including an isolation layer structure in accordance with example embodiments.

Referring to FIG. 18, a computer system 700 may include a memory 510 and a central processing unit (CPU) 710 connected to the memory 510. For example, the computer system 700 may be a personnel computer, a personnel data assistant, etc. The memory 510 may be connected to the CPU 710 directly or connected thereto using a BUS, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive subject matter. Accordingly, all such modifications are intended to be included within the scope of the present inventive subject matter as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. An isolation structure, comprising:
an oxide region in a lower portion of a trench on a substrate;
an oxide layer conforming to a sidewall of the trench in an upper portion of the trench above the oxide region; and
a nitride region in the upper portion of the trench on the oxide region and the oxide layer.

2. The isolation structure of claim 1, wherein the substrate comprises silicon, wherein the oxide region comprises silicon oxide, and wherein the nitride region comprises silicon nitride.

3. The isolation structure of claim 1, wherein the oxide region has a thickness of more than half of a height from a bottom of the trench to a top of the trench.

4. A method of forming an isolation structure, the method comprising:
forming a trench in a substrate;
forming an oxide region in a lower portion of the trench, leaving a portion of a sidewall of the trench above the oxide region exposed;
forming an oxide layer on the exposed sidewall of the trench; and
forming a nitride region in an upper portion of the trench on the oxide region and the oxide layer.

5. The method of claim 4, wherein forming an oxide region in a lower portion of the trench comprises:
forming an oxide layer on the substrate, filling the trench;
planarizing to expose the substrate; and
etching a portion of the oxide layer remaining in an upper portion of the trench to leave the oxide region in the lower portion of the trench.

6. The method of claim 4, wherein forming a nitride region in an upper portion of the trench comprises:
forming a nitride layer on the substrate and on the oxide region and the oxide layer in the trench; and
planarizing to expose the substrate and leave the nitride region in the upper portion of the trench.

7. The method of claim 4, wherein forming an oxide layer on the exposed portion of the sidewall of the trench comprises thermally oxidizing the exposed portion of the sidewall of the trench.

8. The method of claim 4, wherein the substrate comprises silicon, wherein the oxide region comprises silicon oxide, and wherein the nitride region comprises silicon nitride.

9. A semiconductor device, comprising:
a substrate;
an isolation structure including:
an oxide region disposed in a lower portion of a trench in the substrate;
an oxide layer conforming to a sidewall of the trench above the oxide region; and
a nitride region disposed on the oxide region in the trench;
a buried gate structure in the substrate adjacent the isolation structure; and
an impurity region disposed between the buried gate structure and the isolation structure.

10. The semiconductor device of claim 9, wherein the trench comprises a first trench and wherein the buried gate structure comprises a gate insulation layer, a gate electrode and a capping layer pattern in a second trench on the substrate.

11. The semiconductor device of claim 10, wherein the gate electrode comprises a metal.

12. The semiconductor device of claim 10, wherein the gate insulation layer conforms to a sidewall of the second trench and wherein the gate electrode and the capping layer pattern are disposed in the second trench.

13. The semiconductor device of claim 9, wherein the buried gate structure and the impurity region are components of a transistor.

14. The semiconductor device of claim 9, wherein the substrate has a cell region and a peripheral circuit region, wherein memory cells are disposed in the cell region, wherein peripheral circuits are disposed in the peripheral region, wherein the buried gate structure is disposed in the cell region and wherein the semiconductor device further comprises a gate structure in the peripheral region.

15. The semiconductor device of claim 9, wherein the impurity region comprises a plurality of impurity regions and wherein the semiconductor device further comprises a bit line electrically connected to a first one of the impurity regions and a capacitor electrically connected to a second one of the impurity regions.

16. The semiconductor device of claim 9, wherein the substrate comprises silicon, wherein the oxide region comprises silicon oxide, and wherein the nitride region comprises silicon nitride.

17. The semiconductor device of claim 9, wherein the oxide region has a thickness of more than half of a distance from a bottom of the trench to a top of the trench.
